(19) United States
(12) Patent Application Publication
(10) Pub. No.: US 2026/0271587 A1
(43) Pub. Date: Sep. 10, 2026

(54) DISPLAY PANEL AND MANUFACTURING METHOD THEREOF, AND DISPLAY DEVICE

(71) Applicants: Beijing BOE Technology Development Co., Ltd., Beijing (CN); BOE Technology Group Co., Ltd., Beijing (CN)

(72) Inventors: Xiaohu LI, Beijing (CN); Hongli WANG, Beijing (CN); Xu LIU, Beijing (CN); Tong WU, Beijing (CN); Che AN, Beijing (CN); Wenqi LIU, Beijing (CN); Qian JIN, Beijing (CN); Tianhao LU, Beijing (CN); Zhiqiang JIAO, Beijing (CN); Guangcai YUAN, Beijing (CN)

(73) Assignees: Beijing BOE Technology Development Co., Ltd., Beijing (CN); BOE Technology Group Co., Ltd., Beijing (CN)

(21) Appl. No.: 19/110,474

(22) PCT Filed: Aug. 29, 2024
(86) PCT No.: PCT/CN2024/115595

§ 371 Date: Mar. 11, 2025

(30) Foreign Application Priority Data
Sep. 19, 2023 (CN) 202311213885.9

(51) Int. Cl. H10K 59/80; H10K 59/12

(52) U.S. Cl. CPC H10K 59/873; H10K 59/1201; H10K 59/879

(57) ABSTRACT

The present disclosure relates to the field of display technology and discloses a display panel, a manufacturing method thereof, and a display device. The display panel includes a display substrate, an encapsulation layer group, and a first light enhancement layer. The display substrate includes a plurality of sub-pixels. The encapsulation layer group is provided on a light-emitting side of the display substrate, and the encapsulation layer group includes at least two stacked organic film layers. The first light enhancement layer is provided on a side of the encapsulation layer group away from the display substrate. The first light enhancement layer includes a plurality of protruding portions, and orthographic projections of the protruding portions on the display substrate at least partially overlap with the sub-pixels.

### CROSS-REFERENCE TO RELATED APPLICATIONS

The present disclosure is a U.S. National Stage of International Application No. PCT/CN2024/115595 filed on Aug. 29, 2024, which claims the benefit of priority to Chinese patent application number 202311213885.9 filed on Sep. 19, 2023, both of which are incorporated herein by reference in their entireties for all purposes.

### TECHNICAL FIELD

The present disclosure relates to the field of display technology, and in particular, to a display panel and a manufacturing method thereof, and a display device.

### BACKGROUND

The display panel of the diode light-emitting device can meet the new needs of consumers for display technology because of its advantages of high light-dark contrast, fast picture refresh response speed, wide spatial viewing angle, wide ambient temperature adaptability range, high color rendering index, etc. The external quantum efficiency of the display panel is generally only 20%, and most of the light energy will be consumed in the form of metal surface plasma, or consumed due to the optical waveguide mode of total reflection caused by the difference in the refractive index of the film medium.

It should be noted that the information disclosed in the above background technology section is only used to enhance the understanding of the background of the present disclosure, and therefore may include information that does not constitute prior art known to those skilled in the art.

### SUMMARY

According to an aspect of the present disclosure, there is provided a display panel, including:

a display substrate, including a plurality of sub-pixels;
an encapsulation layer group, provided on a light-emitting side of the display substrate, where the encapsulation layer group includes at least two stacked organic film layers; and
a first light enhancement layer, provided on a side of the encapsulation layer group away from the display substrate, where the first light enhancement layer includes a plurality of protruding portions, and orthographic projections of the protruding portions on the display substrate at least partially overlapping with the sub-pixels.

According to another aspect of the present disclosure, there is provided a method for manufacturing a display panel, including:
providing a display substrate, where the display substrate includes a plurality of sub-pixels;
forming an encapsulation layer group on a light-emitting side of the display substrate, where the encapsulation layer group includes at least two stacked organic film layers; and
forming a first light enhancement layer on a side of the encapsulation layer group away from the display substrate, where the first light enhancement layer includes a plurality of protruding portions, and orthographic projections of the protruding portions on the display substrate at least partially overlap with the sub-pixels.

According to still another aspect of the present disclosure, there is provided a display device, including:
a display panel according to any one of the above display panels.

It should be understood that the above general description and the detailed description below are only exemplary and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. Obviously, the drawings described below are only some embodiments of the present disclosure. For those skilled in the art, other drawings can also be obtained based on these drawings without creative work.

FIG. 1 is a structural schematic diagram of a first example embodiment of the display panel of the present disclosure.

FIG. 2 is a schematic diagram of the size relationship between the protruding portion and the encapsulation layer group and the sub-pixel in the display panel of the present disclosure.

FIG. 3 is a schematic diagram of the comparison of the gain of the sub-pixel on-axis luminance before and after the thickness of the encapsulation layer group 2 is simulated to be increased.

FIG. 4 is a structural schematic diagram of a second example embodiment of the display panel of the present disclosure.

FIG. 5 is a schematic diagram of the optical path of the outgoing light of an example embodiment of the display panel of the present disclosure.

FIG. 6 is a structural schematic diagram of a third example embodiment of the display panel of the present disclosure.

FIG. 7 is a structural schematic diagram of a fourth example embodiment of the display panel of the present disclosure.

FIG. 8 is a top view schematic diagram of a fifth example embodiment of the display panel of the present disclosure.

FIG. 9 is a structural schematic diagram of a sixth example embodiment of the display panel of the present disclosure.

FIG. 10 is a schematic flow chart of an example embodiment of a method for manufacturing a display panel of the present disclosure.

FIG. 11 to FIG. 15 are schematic structural diagrams at various steps in the manufacturing process of the encapsulation layer group in the method for manufacturing the display panel of the present disclosure.

### EXPLANATION OF REFERENCE NUMERALS

1. Display substrate; 11. Base substrate; 12. Driving backplane; 13. First planarization layer; 14. Pixel definition layer; 15. Light-emitting device; 151. First electrode; 152. Light-emitting layer group; 153. Second electrode; 16. Light extraction layer; 17. Sub-pixel;
2. Encapsulation layer group; 21. First inorganic layer; 22. Organic film layer; 22a. First organic layer; 22a1. Concave structure; 22b. Second organic layer; 22b1. Protruding structure; 23. Leveling enhancement layer; 24. Second inorganic layer;
3. Buffer layer;
4. First light enhancement layer; 41. Protruding portion;
5. Planarization layer; 6. Second light enhancement layer.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and the concepts of the example embodiments will be fully conveyed to those skilled in the art. The same reference numerals in the figures represent the same or similar structures, and their detailed descriptions will be omitted. In addition, the drawings are only schematic illustrations of the present disclosure and are not necessarily drawn to scale.

Although relative terms such as “upper” and “lower” are used in this description to describe the relative relationship of one component of the icon to another component, these terms are used in the description only for convenience, such as according to the direction of the examples described in the drawings. It is understood that if the device of the icon is flipped so that it is upside down, the component described as “upper” will become the component “lower”. When a structure is “on” another structure, it may mean that a structure is formed integrally on the other structure, or that a structure is “directly” set on the other structure, or that a structure is “indirectly” set on the other structure through another structure.

The terms “a”, “an”, “the”, “said” and “at least one” are used to indicate the existence of one or more elements/components/etc.; the terms “including” and “having” are used to indicate an open-ended inclusion and mean that there may be other elements/components/etc. in addition to the listed elements/components/etc.; the terms “first”, “second” and “third” are used only as markers and are not quantitative restrictions on their objects.

In this application, unless otherwise clearly specified and limited, the term “connection” should be understood in a broad sense. For example, “connection” can be a fixed connection, a detachable connection, or an integral connection; it can be a direct connection or an indirectly connection through an intermediate medium. “And/or” is only a description of the association relationship of the associated objects, indicating that there can be three relationships. For example, A and/or B can represent: A exists alone, A and B exist at the same time, and B exists alone. In addition, the character “/” herein generally indicates that the associated objects before and after are in an “or” relationship.

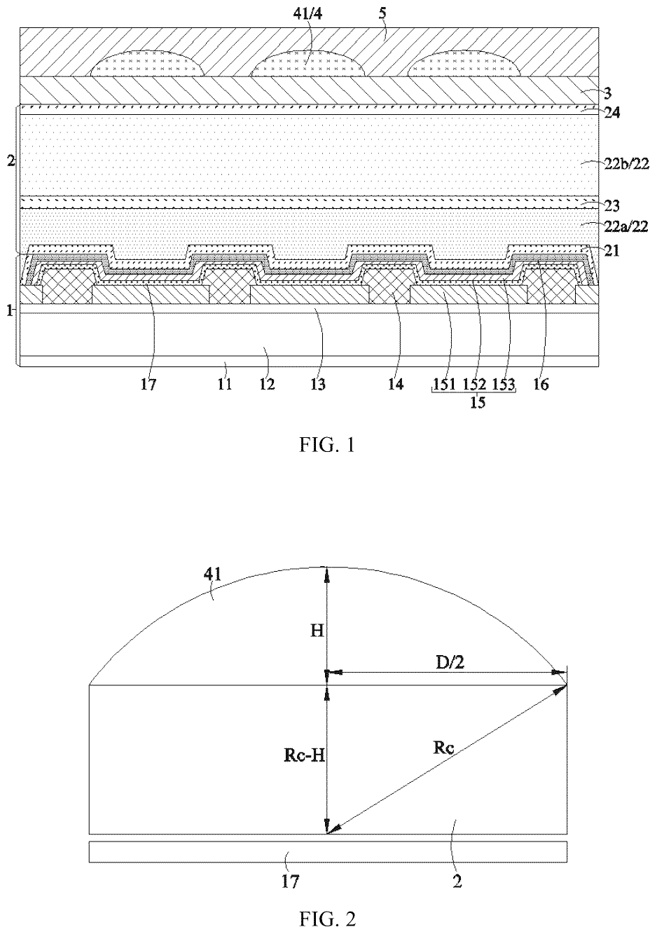

The example embodiment of the present disclosure provides a display panel, as shown in FIG. 1. The display panel may include a display substrate 1, an encapsulation layer group 2, and a first light enhancement layer 4. The display substrate 1 may include a plurality of sub-pixels 17. The encapsulation layer group 2 is provided on the light-emitting side of the display substrate 1, and the encapsulation layer group 2 may include at least two stacked organic film layers 22. The first light enhancement layer 4 is provided on a side of the encapsulation layer group 2 away from the display substrate 1. The first light enhancement layer 4 includes a plurality of protruding portions 41, and the orthographic projection of the protruding portion 41 on the display substrate 1 overlaps at least partially with the sub-pixel 17.

The display panel of the present disclosure, on the one hand, is provided with a first light enhancement layer 4 on the side of the encapsulation layer group 2 away from the display substrate 1, and the first light enhancement layer 4 includes a plurality of protruding portions 41. The light emitted by the sub-pixel 17 can be converged by the protruding portions 41, so that the light with a larger inclination angle has reduced exit angle and is emitted from the front of the display panel, thereby increasing the front light extraction efficiency of the display panel to reduce the power consumption of the display panel and reducing the cross-color of two adjacent sub-pixels 17. On the other hand, the encapsulation layer group 2 includes at least two layers of stacked organic film layers 22, so that the thickness of the encapsulation layer group 2 is increased. The front light extraction efficiency of the display panel can be maximized through the protruding portion 41 to reduce the power consumption of the display panel.

The display substrate 1 can be an OLED (Organic Electroluminescence Display, organic light-emitting semiconductor) display substrate 1, a QLED (Quantum Dot Light Emitting Diodes) display substrate 1, a Micro-LED (Micro-light emitting diode) display substrate 1, etc.; the display substrate 1 has a light-emitting side and a non-light-emitting side, the light-emitting side is arranged opposite to the non-light-emitting side, and picture can be displayed at the light-emitting side, and the side at which the picture is displayed is the display surface.

In this example embodiment, taking the OLED display substrate 1 as an example, the display substrate 1 may include a base substrate 11, a driving backplane 12 and a light-emitting device 15, and the driving backplane 12 can drive the light-emitting device 15 to emit light.

The driving backplane 12 may include a plurality of switch units. The switch units may include a plurality of thin film transistors, and the plurality of switch units are arranged in an array. A first planarization layer 13 is provided on the side of the plurality of switch units away from the base substrate 11, and the first planarization layer 13 provides a relatively flat base surface for the film layer to be formed subsequently.

A light-emitting device 15 is provided on the side of the first planarization layer 13 away from the base substrate 11, and the light-emitting device 15 may include a first electrode 151, a light-emitting layer group 152, and a second electrode 153.

Specifically, a first electrode 151 is provided on the side of the first planarization layer 13 away from the base substrate 11. The first electrode 151 is connected to the source electrode of the driving backplane 12, and the first electrode 151 may be an anode.

A pixel definition layer 14 is provided on the side of the first electrode 151 away from the base substrate 11. A via is provided on the pixel definition layer 14, and a light-emitting layer group 152 is provided in the via. A second electrode 153 is provided on the side of the light-emitting layer group 152 away from the base substrate 11. The second electrode 153 may be a cathode and connected to the ground line VSS. The light-emitting layer group 152 in a via emits light to form a sub-pixel 17. Therefore, the light-emitting layer group 152 in a via is a sub-pixel 17, so that the orthogonal projection of the sub-pixel 17 on the display substrate 1 is the orthogonal projection of the light-emitting layer group 152 on the display substrate 1. The display substrate 1 may include a plurality of sub-pixels 17.

The light-emitting layer group 152 may include a hole injection layer, a hole transport layer, a light-emitting layer, an electron transport layer and an electron injection layer stacked in sequence. The hole injection layer contacts the first electrode 151, and the electron injection layer contacts the second electrode 153. Of course, in other example embodiments of the present disclosure, the light-emitting layer group 152 may only include a hole transport layer, a light-emitting layer and an electron transport layer. The light-emitting layer group 152 may also be other structures, and its specific structure may be set as needed.

A light extraction layer 16 (Capping Layer, CPL) can be provided on the light emitting side of the display substrate 1. The light extraction layer 16 can improve the light emitting mode of the display substrate 1, so that the light originally confined inside the display substrate 1 can be emitted from the display substrate 1, showing a higher light extraction efficiency. Of course, the light extraction layer 16 can be omitted.

An encapsulation layer group 2 is provided on the side of the light extraction layer 16 away from the base substrate 11. The encapsulation layer group 2 is configured to encapsulate the display substrate 1 to prevent external water vapor, impurities, etc. from entering the display substrate 1 and affecting the display effect of the display substrate 1.

A first light enhancement layer 4 is provided on the side of the encapsulation layer group 2 away from the display substrate 1. The first light enhancement layer 4 may include a plurality of protruding portions 41. The orthographic projection of the protruding portion 41 on the display substrate 1 at least partially overlaps with the sub-pixel 17. For example, the orthographic projection of the protruding portion 41 on the display substrate 1 may cover the sub-pixel 17, or the orthographic projection of the protruding portion 41 on the display substrate 1 may coincide with the sub-pixel 17, or a part of the orthographic projection of the protruding portion 41 on the display substrate 1 may cover a part of the sub-pixel 17. The refractive index of the first light enhancement layer 4 is greater than or equal to 1.65.

The light emitted by the sub-pixel 17 can be converged by the protruding portion 41, so that the light with a larger inclination angle has a reduced exit angle and is emitted from the front of the display panel, thereby increasing the front light extraction efficiency of the display panel to reduce the power consumption of the display panel; and reducing the cross-color of two adjacent sub-pixels 17.

However, it is found from experiments that the light extraction efficiency increased by the protruding portion 41 of the first light enhancement layer 4 is relatively limited. The inventors found that the main reason for this result is that the curvature radius of the protruding portion 41 is large, resulting in the sub-pixel 17 not being set at the optimal light extraction position of the protruding portion 41, and the light extraction efficiency of the display panel cannot be maximized.

Referring to FIG. 2, Rc is the curvature radius of the protruding portion 41, H is the arch height of the protruding portion 41, and D is the opening size of the protruding portion 41. According to the trigonometric relationship Rc²=(D/2)²+(Rc-H)², it can be obtained that Rc=H/2+D²/8H. Under normal circumstances, H can be set to 10 μm (micrometers), and D can be set to 50 μm; thus, Rc can be obtained to be 36.25 μm.

Moreover, the relationship between the focal length of the protruding portion 41 and the curvature radius of the protruding portion 41 is fμ=Rc/Δn, where fμ is the focal length of the protruding portion 41, and Δn is the difference in refractive index between the protruding portion 41 and the material on the side of the protruding portion 41 away from the encapsulation layer group 2. Normally, Δn is about 0.35, then fμ is about 103.5 μm, which is much larger than the current thickness of the encapsulation layer group 2.

The focal length of the protruding portion 41 can be reduced by reducing the curvature radius Rc of the protruding portion 41. However, due to the current manufacturing process of the protruding portion 41 and the thickness limit of the film layer of the protruding portion 41, the curvature radius Rc of the protruding portion 41 cannot be reduced. Specifically, in a case where the protruding portion 41 is formed by printing, the curvature radius Rc of the protruding portion 41 depends on the liquid repellency of the buffer layer 3. Generally, the stronger the liquid repellency of the buffer layer 3, the higher the arch height of the protruding portion 41. However, the material of the buffer layer 3 is generally determined, so the curvature radius Rc of the protruding portion 41 is also a determined value. In a case where the protruding portion 41 is formed by photolithography, the higher the arch height of the protruding portion 41, the thicker the required thickness, which makes it easy to form a planar structure in the middle part of the protruding portion 41, and thus it is impossible to achieve the convergence of light.

As shown in FIG. 3, by simulating the thickness of the encapsulation layer group 2 to be increased within a certain range, and the gain of the on-axis luminance increases significantly.

It can be seen from the figure that the thickness of the encapsulation layer group 2 is simulated to be increased from about 13.5 μm to about 21.5 μm, the gain of the on-axis luminance of the blue sub-pixel B increases from about 123% to about 135%, the gain of the on-axis luminance of the green sub-pixel G increases from about 122% to about 133%, and the gain of the on-axis luminance of the red sub-pixel R increases from about 121% to about 132%, all of which increase by more than about 10%.

In this example embodiment, the encapsulation layer group 2 may include at least two stacked organic film layers 22, that is, the thickness of the encapsulation layer group 2 is increased by adding the organic film layer 22. Thus, the sub-pixel 17 is closer to the optimal light extraction position of the protruding portion 41, so that the front light extraction efficiency of the display panel can be greatly improved through the protruding portion 41.

Refer to Table 1 for a comparison of the light efficiency gains of green and blue sub-pixels in a case where the thickness of the encapsulation layer group 2 is the conventional thickness of the prior art (the thickness of the encapsulation layer group 2 is about 15 μm) and in a case where the thickness of the encapsulation layer group 2 is the increased thickness of the present disclosure (the thickness of the encapsulation layer group 2 is about 30 μm).

TABLE 1

| Sub-pixel | Green Sub-pixel | | Blue Sub-pixel | |
|---|---|---|---|---|
| Thickness of the | Conventional | Increased | Conventional | Increased |
| encapsulation layer | thickness | thickness | thickness | thickness |
| group | (15 μm) | (30 μm) | (15 μm) | (30 μm) |
| Light efficiency | 115.21% | 130.27% | 114.12% | 124.90% |
| gain | | | | |
| (conventional | | | | |
| 100%) | | | | |

It can be seen from Table 1 and FIG. 3 that the actual effect is consistent with the simulation effect. By increasing the thickness of the encapsulation layer group 2, the sub-pixel 17 can be closer to the optimal light extraction position of the protruding portion 41, so that the front light extraction efficiency of the display panel can be improved to a greater extent through the protruding portion 41.

As shown in FIG. 1, the encapsulation layer group 2 may include at least two layers of stacked organic film layers 22, that is, the encapsulation layer group 2 may include two organic film layers 22, three organic film layers 22 or more organic film layers 22. The thickness of the encapsulation layer group 2 is increased by increasing the number of the organic film layers 22. Since the thickness of the organic film layer 22 is relatively thick, the thickness of the encapsulation layer group 2 can be effectively increased by increasing the number of the organic film layers 22. The thickness of the inorganic film layer is relatively thin, and even if the thickness of the inorganic film layer is increased, the thickness of the encapsulation layer group 2 cannot be effectively increased. Furthermore, the organic film layer 22 is relatively soft, and even if the number of the organic film layers 22 is increased, the bending effect of the display panel is not greatly affected. However, the material of the inorganic film layer is relatively brittle, and increasing the thickness or number of the inorganic film layer will seriously affect the bending effect of the display panel. Moreover, the thicker inorganic film layer is prone to fall off and warp, affecting the display effect of the display panel.

In this example embodiment, as shown in FIG. 1, the encapsulation layer group 2 may include a first inorganic layer 21, provided on the light-emitting side of the display substrate 1. The material of the first inorganic layer 21 may be SiN (silicon nitride), SiO (silicon oxide) or SiNO (silicon oxynitride), etc.

The thickness of the first inorganic layer 21 is greater than or equal to 0.1 μm and less than or equal to 2 μm. For example, the thickness of the first inorganic layer 21 can be 0.15 μm, 0.2 μm, 0.25 μm, 0.3 μm, 0.35 μm, 0.4 μm, 0.45 μm, 0.5 μm, 0.55 μm, 0.6 μm, 0.65 μm, 0.7 μm, 0.75 μm, 0.8 μm, 0.85 μm, 0.9 μm, 0.95 μm, 1 μm, 1.05 μm, 1.1 μm, 1.15 μm, 1.2 μm, 1.25 μm, 1.3 μm, 1.35 μm, 1.4 μm, 1.45 μm, 1.5 μm, 1.55 μm, 1.6 μm, 1.65 μm, 1.7 μm, 1.75 μm, 1.8 μm, 1.85 μm, 1.9 μm, 1.95 μm, etc.

At least two stacked organic film layers 22 form an organic film layer group. The organic film layer group is provided on the side of the first inorganic layer 21 away from the display substrate 1, so that the first inorganic layer 21 is provided between the display substrate 1 and the organic film layer 22 group.

The organic film layer 22 is generally formed by printing. That is, the liquid of the organic material is formed on the light-emitting side of the display substrate 1 by printing, and the liquid of the organic material is solidified to form the organic film layer 22. Therefore, the thickness of the organic film layer 22 printed once cannot be too thick. If it is too thick, it is not easy to solidify, which affects the production efficiency. Even if it is barely solidified, it is easy to cause stress concentration; and too thick liquid of organic material will cause overflow, abnormal leveling and other problems.

By printing at least twice to form at least two stacked organic film layers 22, the overall thickness of the organic film layer 22 can be increased by multiples, thereby increasing the thickness of the encapsulation layer group 2.

The following is an example of at least two organic film layers 22 including two organic film layers 22. That is, at least two stacked organic film layers 22 can include a first organic layer 22a and a second organic layer 22b.

The first organic layer 22a is provided on the light-emitting side of the display substrate 1. Specifically, the first organic layer 22a is provided on the side of the first inorganic layer 21 away from the display substrate 1. The first organic layer 22a can be formed by printing. The thickness of the first organic layer 22a is greater than or equal to 2 μm and less than or equal to 15 μm. For example, the thickness of the first organic layer 22a can be 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, etc.

The refractive index of the first organic layer 22a is about 1.4.

The second organic layer 22b is provided on the side of the first organic layer 22a away from the display substrate 1, and the second organic layer 22b can be formed by printing.

Specifically, the refractive index of the second organic layer 22b is about 1.65.

However, the surface of the cured first organic layer 22a is a liquid-repellent structure, which is not conducive to the leveling of the liquid of the subsequently printed organic material, resulting in poor flatness of the subsequently formed second organic layer 22b, and affecting the display effect of the display panel; and, the liquid of the subsequently printed organic material is prone to overflow and other problems.

Further, a leveling enhancement layer 23 is provided between two adjacent organic film layers 22, that is, a leveling enhancement layer 23 is provided between the first organic layer 22a and the second organic layer 22b. The leveling enhancement layer 23 can change the liquid repellency of the surface of the first organic layer 22a. Specifically, the hydrophilicity of the leveling enhancement layer 23 is stronger than the hydrophilicity of the organic film layer 22 close to the display substrate 1. In the case of two organic film layers 22, the hydrophilicity of the leveling enhancement layer 23 is stronger than the hydrophilicity of the first organic layer 22a. The leveling enhancement layer 23 allows the liquid of the subsequently formed organic material to be well leveled, so that the flatness of the second organic layer 22b formed after curing is better to ensure the display effect of the display panel; and the liquid of the subsequently formed organic material is not prone to overflow and other problems.

Specifically, as shown in FIG. 2, the material of the leveling enhancement layer 23 can be an inorganic material. For example, the material of the leveling enhancement layer 23 can be SiN (silicon nitride), SiO (silicon oxide) or SiNO (silicon oxynitride), etc. The thickness of the leveling enhancement layer 23 is greater than or equal to 0.05 μm and less than or equal to 2 μm. For example, the thickness of the leveling enhancement layer 23 can be 0.1 μm, 0.15 μm, 0.2 μm, 0.25 μm, 0.3 μm, 0.35 μm, 0.4 μm, 0.45 μm, 0.5 μm, 0.55 μm, 0.6 μm, 0.65 μm, 0.7 μm, 0.75 μm, 0.8 μm, 0, 85 μm, 0.9 μm, 0.95 μm, 1 μm, 1.05 μm, 1.1 μm, 1.15 μm, 1.2 μm, 1.25 μm, 1.3 μm, 1.35 μm, 1.4 μm, 1.45 μm, 1.5 μm, 1.55 μm, 1.6 μm, 1.65 μm, 1.7 μm, 1.75 μm, 1.8 μm, 1.85 μm, 1.9 μm, 1.95 μm, etc.

Of course, in some other example embodiments of the present disclosure, the material of the leveling enhancement layer 23 can be an organic material, as long as the hydrophilicity of the organic material meets the requirements. For example, the material of the leveling enhancement layer 23 can be acrylic, polyurethane, etc. In this case, the thickness of the leveling enhancement layer 23 is less than or equal to 10 μm. For example, the thickness of the leveling enhancement layer 23 can be 1 μm, 2 μm, 3 μm, 4 μm, 5 μm, 6 μm, 7 μm, 8 μm, 9 μm, etc.

Moreover, the refractive index of the organic film layer 22 away from the display substrate 1 is greater than the refractive index of the leveling enhancement layer 23. That is, the refractive index of the second organic layer 22b is greater than the refractive index of the leveling enhancement layer 23. For example, the refractive index of the leveling enhancement layer 23 is about 1.6, which is less than the refractive index of the second organic layer 22b mentioned above, which is 1.65. Similarly, the light is emitted from the material with a lower refractive index to the material with a higher refractive index, so that the emission direction of the light with a larger inclination angle can converge in the front direction, thereby improving the front light extraction efficiency of the display panel.

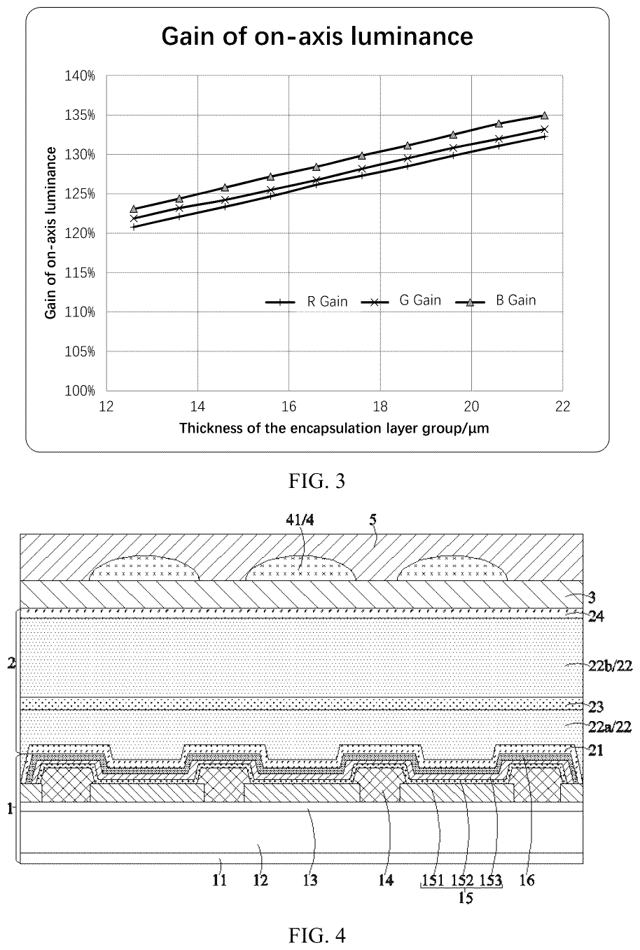

In addition, in some other example embodiments of the present disclosure, as shown in FIG. 4, the leveling enhancement layer 23 can be a surface fluoridation layer or a surface microstructure layer of the organic film layer 22 closer to the display substrate 1. That is, the leveling enhancement layer 23 can be a surface fluoridation layer or a surface microstructure layer of the first organic layer 22a. The surface fluoridation layer is formed by plasma treatment of fluorine ions, and the surface fluoridation layer can change the liquid repellency of the surface of the first organic layer 22a, which can also be said to have better liquid lyophilic property.

The surface microstructure layer is formed by plasma treatment of oxygen ions, and the surface of the first organic layer 22a is bombarded by oxygen ions so that an uneven structure layer is formed on the surface of the first organic layer 22a, and the uneven structure layer is a surface microstructure layer. The surface microstructure layer can change the contact angle of the surface of the first organic layer 22a. That is, the contact angle of the surface microstructure layer is smaller. That is also can be said that the surface microstructure layer has a better liquid lyophilic property.

Thus, the surface fluoridation layer or the surface microstructure layer allows the liquid of the organic material formed subsequently to be well leveled, and the second organic layer 22b formed after curing has a good flatness to ensure the display effect of the display panel; and the liquid of the organic material formed subsequently is not prone to overflow and other problems.

In addition, the surface fluoridation layer can reduce the surface polarity of the first organic layer 22a, inhibit the formation of hydrogen bonds, and combine with oxygen in the buffer layer 3, so as to slow down the diffusion of water vapor, improve the barrier performance of the encapsulation layer group 2, and thus improve the encapsulation reliability.

In this case, the thickness of the second organic layer 22b can be made thicker. Specifically, the thickness of the second organic layer 22b is greater than or equal to 5 μm and less than or equal to 20 μm. For example, the thickness of the second organic layer 22b can be 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm and the like.

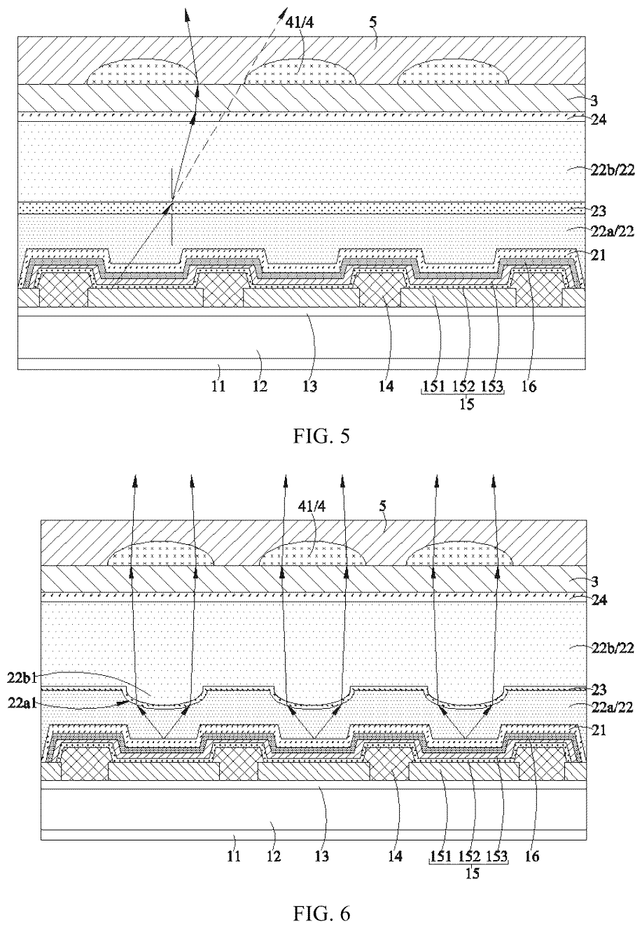

As shown in FIG. 5, the dotted line in the figure is a comparative optical path. The refractive indexes of at least two organic film layers 22 increase with the increase of the distance from the display substrate 1. For example, in the case of two organic film layers 22, the refractive index of the second organic layer 22b is greater than the refractive index of the first organic layer 22a; in the case of three organic film layers 22, the refractive index of the second organic layer 22b is greater than the refractive index of the first organic layer 22a, and the refractive index of the third organic film layer 22 is greater than the refractive index of the second organic layer 22b. The light is emitted from the material with a lower refractive index to the material with a higher refractive index, so that the emission direction of the light with a larger inclination angle can converge in the front direction, thereby improving the front light extraction efficiency of the display panel.

Further, referring to FIG. 6 to FIG. 8, a concave structure 22al is provided on one side of the first organic layer 22a close to the leveling enhancement layer 23. That is, a concave structure 22al is provided on one side of the first organic layer 22a away from the display substrate 1, and the part of the second organic layer 22b located in the concave portion forms a protruding structure 22b1.

The concave structure 22al can be formed by embossing or exposure, and then the leveling enhancement layer 23 is formed on the side of the first organic layer 22a away from the display substrate 1. Since the thickness of the leveling enhancement layer 23 is relatively thin, the concave structure 22al is still retained after the leveling enhancement layer 23 is formed. The specific structure of the leveling enhancement layer 23 has been described in detail above, so it will not be repeated here. Finally, the second organic layer 22b is formed on the side of the leveling enhancement layer 23 away from the display substrate 1, and a part of the second organic layer 22b will be formed in the concave portion to form a protruding structure 22b1.

The protruding structure 22b1 forms a converging lens to converge the light incident on the protruding structure 22b1, so that the light with a larger inclination angle has a reduced exit angle and is emitted from the front of the display panel, thereby increasing the front light extraction efficiency of the display panel to reduce the power consumption of the display panel.

As shown in FIG. 6, the orthographic projection of one protruding structure 22b1 on the display substrate 1 overlaps at least partially with one sub-pixel 17. For example, the orthographic projection of one protruding structure 22b1 on the display substrate 1 may cover one sub-pixel 17, or the orthographic projection of one protruding structure 22b1 on the display substrate 1 may coincide with one sub-pixel 17, or the orthographic projection of one protruding structure 22b1 on the display substrate 1 may cover a part of one sub-pixel 17.

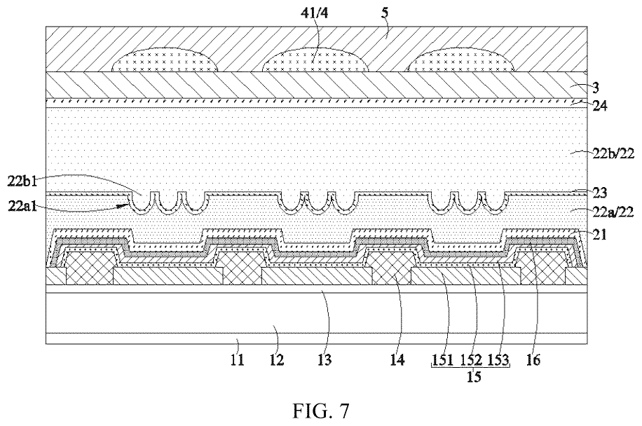

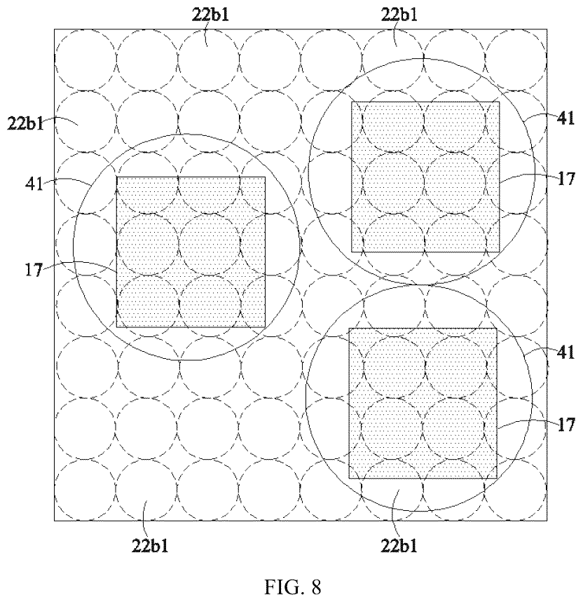

Referring to FIG. 7 and FIG. 8, the protruding structure 22b1 is blocked and thus indicated by a dotted line in FIG. 8. In some other example embodiments of the present disclosure, the orthogonal projections of the multiple protruding structures 22b1 on the display substrate 1 overlap at least partially with one sub-pixel 17. That is, the concave structure 22al and the protruding structure 22b1 are set smaller, so that the orthogonal projection area of the protruding structure 22b1 on the display substrate 1 is smaller than the area of the sub-pixel 17, and the orthogonal projections of the multiple protruding structures 22b1 on the display substrate 1 can cover one sub-pixel 17.

Referring to FIG. 7, the concave structure 22al and the protruding structure 22b1 may not be provided between adjacent sub-pixels 17. As shown in FIG. 8, the concave structure 22al and the protruding structure 22b1 may also be provided between adjacent sub-pixels 17, so that the display area of the entire display panel is provided with the concave structure 22al and the protruding structure 22b1, which is convenient for the design of technicians and simplifies the manufacturing process. There is no need to limit the apparatus to which areas the concave structure 22al and the protruding structure 22b1 are formed and which areas the concave structure 22a1 and the protruding structure 22b1 are not formed.

In this example embodiment, as shown in FIG. 1, the encapsulation layer group 2 may also include a second inorganic layer 24. The second inorganic layer 24 is provided on the side of the organic film layer 22 group away from the display substrate 1. Specifically, the second inorganic layer 24 is provided on the side of the second organic layer 22b away from the display substrate 1. The second inorganic layer 24 can improve the water and oxygen barrier properties of the encapsulation layer group 2. The material of the second inorganic layer 24 can be SiN. The thickness of the second inorganic layer 24 is greater than or equal to 0.5 μm and less than or equal to 2 μm. For example, the thickness of the second inorganic layer 24 can be 0.55 μm, 0.6 μm, 0.65 μm, 0.7 μm, 0.75 μm, 0.8 μm, 0.85μ, 0.9μ, 0.95 μm, 1μ, 1.05μm, 1.1 μm, 1.15 μm, 1.2 μm, 1.25 μm, 1.3 μm, 1.35 μm, 1.4 μm, 1.45 μm, 1.5 μm, 1.55 μm, 1.6 μm, 1.65 μm, 1.7 μm, 1.75 μm, 1.8 μm, 1.85 μm, 1.9 μm, 1.95 μm, etc.

The display panel may also include a buffer layer 3. The buffer layer 3 is provided on a side of the first light enhancement layer 4 close to the encapsulation layer group 2. Specifically, the buffer layer 3 is provided between the second inorganic layer 24 and the first light enhancement layer 4. The material of the buffer layer 3 is a liquid-repellent material. The liquid repellency of the buffer layer 3 is related to the morphology of the protruding portion 41. Generally, the stronger the liquid repellency of the buffer layer 3, the higher the arch height of the protruding portion 41. The buffer layer 3 can make the protruding portion 41 of the first light enhancement layer 4 form a better convex lens morphology, ensuring the light convergence effect of the protruding portion 41.

A planarization layer 5 is provided on the side of the first light enhancement layer 4 away from the display substrate 1. The refractive index of the first light enhancement layer 4 is greater than the refractive index of the planarization layer 5. Specifically, the refractive index of the planarization layer 5 is less than or equal to 1.6, which is less than the refractive index of the first light enhancement layer 4 described above, which is greater than or equal to 1.65. The greater the difference between the refractive index of the planarization layer 5 and the refractive index of the first light enhancement layer 4, that is, the greater the Δn in the above formula, the smaller the focal length of the protruding portion 41. Therefore, the greater the difference between the refractive index of the planarization layer 5 and the refractive index of the first light enhancement layer 4, the smaller the thickness of the encapsulation layer group 2 can be set, and it can be ensured that the sub-pixel 17 can be basically located in the focal plane of the protruding portion 41. However, if the refractive index of the planarization layer 5 is too small, it is difficult to select the material of the planarization layer 5.

Of course, in some other example embodiments of the present disclosure, the planarization layer 5 may not be set.

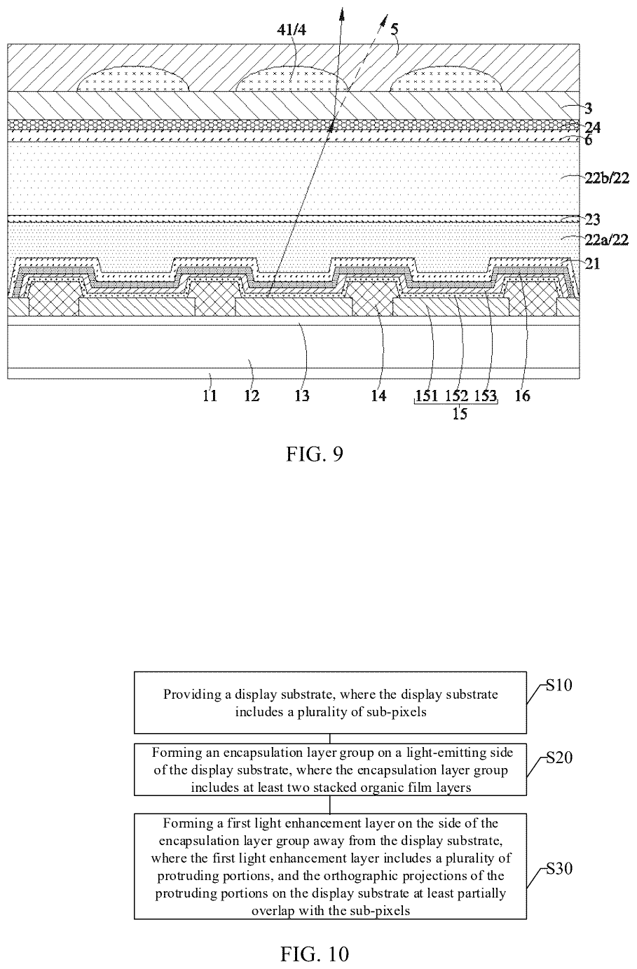

As shown in FIG. 9, in some example embodiments of the present disclosure, the display panel may further include a second light enhancement layer 6. The second light enhancement layer 6 is provided between the first light enhancement layer 4 and the encapsulation layer group 2. Specifically, the second light enhancement layer 6 is provided between the second inorganic layer 24 of the encapsulation layer group 2 and the buffer layer 3. The refractive index of the second light enhancement layer 6 is greater than the refractive index of the film layer adjacent to the second light enhancement layer 6 in the encapsulation layer group 2. That is, the refractive index of the second light enhancement layer 6 is greater than the refractive index of the second inorganic layer 24, so that when the light emitted from the second inorganic layer 24 is emitted to the second light enhancement layer 6, it is emitted from the optically sparse medium to the optically dense medium, and the light with a larger inclination angle will be refracted toward the center position and emitted from the front of the display panel, thereby increasing the front light extraction efficiency of the display panel to reduce the power consumption of the display panel.

Based on the same inventive concept, the example embodiment of the present disclosure provides a method for manufacturing a display panel, as shown in FIG. 10. The manufacturing method may include the following steps:

Step S10, providing a display substrate 1, where the display substrate 1 includes a plurality of sub-pixels 17.

Step S20, forming an encapsulation layer group 2 on a light-emitting side of the display substrate 1, where the encapsulation layer group 2 includes at least two stacked organic film layers 22.

Step S30, forming a first light enhancement layer 4 on the side of the encapsulation layer group 2 away from the display substrate 1, where the first light enhancement layer 4 includes a plurality of protruding portions 41, and the orthographic projections of the protruding portions 41 on the display substrate at least partially overlap with the sub-pixels 17.

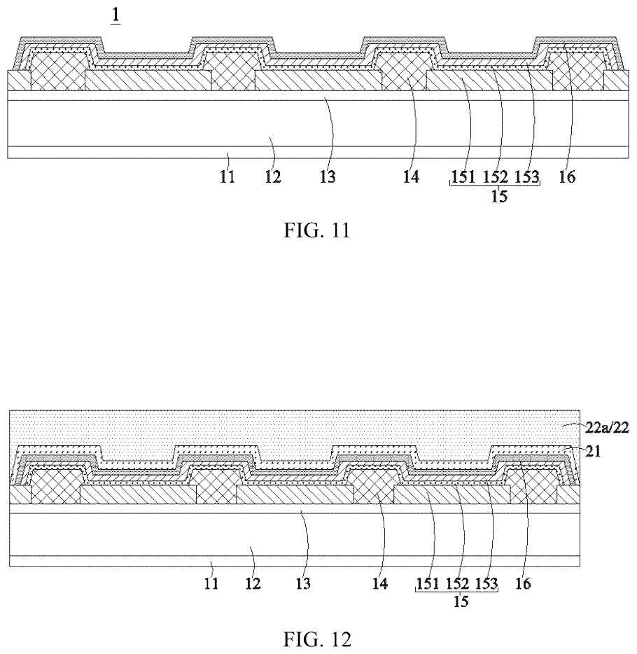

Referring to FIG. 11, a display substrate 1 is provided, and the manufacturing method of the display substrate 1 is a manufacturing method in the prior art, so it is not repeated here.

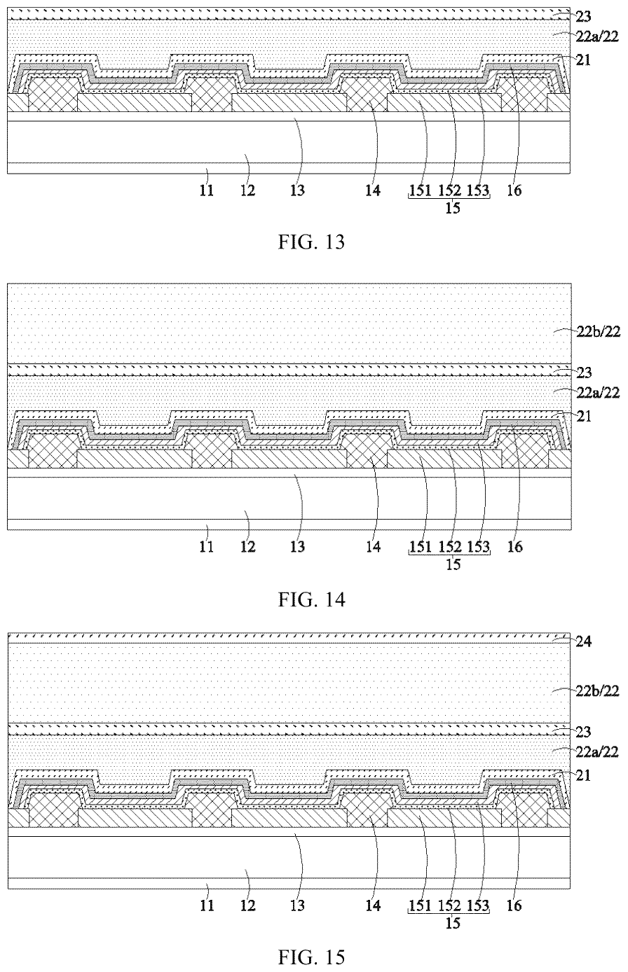

Forming the encapsulation layer group 2 on the light-emitting side of the display substrate 1 may include: as shown in FIG. 12, forming a first inorganic layer 21 on the light-emitting side of the display substrate 1 by chemical vapor deposition or other processes; forming a first organic layer 22a on the side of the first inorganic layer 21 away from the display substrate 1 by printing, coating or other processes. As shown in FIG. 13, the first organic layer 22a is subjected to plasma treatment to form a leveling enhancement layer 23 on the side of the first organic layer 22a away from the display substrate 1. Specifically, the plasma treatment may include fluorination. For example, by NF3 gas, the side of the first organic layer 22a away from the display substrate 1 is fluorinated, and the fluorine ions are inserted into the polymer chain of the first organic layer 22a to form —CF2 and —CF3 bonds, thereby forming a leveling enhancement layer 23. The leveling enhancement layer 23 is a surface fluorination layer to change the liquid repellency of the entire surface of the first organic layer 22a.

Of course, the plasma treatment may include plasma treatment by oxygen ions, bombarding the surface of the first organic layer 22a with oxygen ions to form an uneven structural layer on the surface of the first organic layer 22a, and the uneven structural layer is a surface microstructure layer, so that the surface of the first organic layer 22a forms a surface microstructure layer, and the contact angle of the first organic layer 22a is improved.

As shown in FIG. 14, then, a second organic layer 22b is formed on the side of the leveling enhancement layer 23 away from the display substrate 1 by printing, coating and other processes. The leveling enhancement layer 23 allows the liquid of the organic material formed subsequently to be well leveled, so that the second organic layer 22b formed after curing has a good flatness to ensure the display effect of the display panel.

Of course, as shown in FIG. 15, after the second organic layer 22b is formed, the second inorganic layer 24 can be formed by chemical vapor deposition and other processes. The formation process of the first inorganic layer 21 and the second inorganic layer 24 is a process in the prior art, so it is not repeated here.

The formation process of the first light enhancement layer 4 is a process in the prior art, so it is not repeated here.

It should be noted that although the steps of the method for manufacturing a display panel in the present disclosure are described in a specific order in the accompanying drawings, this does not require or imply that these steps must be performed in this specific order, or that all the steps shown must be performed to achieve the desired result. Additionally, or alternatively, some steps may be omitted, multiple steps may be combined into one step for execution, and/or one step may be decomposed into multiple steps for execution, etc.

Based on the same inventive concept, the example embodiment of the present disclosure provides a display device. The display device may include any of the display panels described above. The specific structure of the display panel has been described in detail above, so it will not be repeated here.

The specific type of the display device is not particularly limited, and any type of display device commonly used in the art may be used, such as mobile devices (e.g., mobile phones), wearable devices (e.g., watches, VR devices), etc. Those skilled in the art may make corresponding choices according to the specific purpose of the display device, which will not be repeated here.

It should be noted that in addition to the display panel, the display device also includes other necessary parts and components, such as a housing, a circuit board, a power cord, etc., taking the display as an example, those skilled in the art may make corresponding supplements according to the specific use requirements of the display device, which will not be repeated here.

Compared with the prior art, the beneficial effects of the display device provided by the example embodiment of the present disclosure are the same as the beneficial effects of the display panel provided by the example embodiment above, which will not be repeated here.

After considering the description and practicing the present disclosure herein, those skilled in the art will easily think of other embodiments of the present disclosure. This application is intended to cover any variation, use or adaptation of the present disclosure, which follows the general principles of the present disclosure and includes common knowledge or customary technical means in the technical field not disclosed in the present disclosure. The description and examples are to be regarded as exemplary only, and the true scope and spirit of the present disclosure are indicated by the appended claims.

1. A display panel, comprising:
a display substrate, comprising a plurality of sub-pixels;
an encapsulation layer group, provided on a light-emitting side of the display substrate, wherein the encapsulation layer group comprises at least two stacked organic film layers; and
a first light enhancement layer, provided on a side of the encapsulation layer group away from the display substrate, wherein the first light enhancement layer comprises a plurality of protruding portions, and orthographic projections of the protruding portions on the display substrate at least partially overlapping with the sub-pixels.

2. The display panel according to claim 1, wherein a leveling enhancement layer is provided between two adjacent organic film layers.

3. The display panel according to claim 2, wherein a hydrophilicity of the leveling enhancement layer is stronger than a hydrophilicity of the organic film layer adjacent to the leveling enhancement layer and closer to the display substrate.

4. The display panel according to claim 3, wherein a material of the leveling enhancement layer is an inorganic material, or the leveling enhancement layer is a surface fluorination layer or a surface microstructure layer of the organic film layer closer to the display substrate.

5. The display panel according to claim 2, wherein a refractive index of the organic film layer adjacent to the leveling enhancement layer and further away from the display substrate is greater than or equal to a refractive index of the leveling enhancement layer.

6. The display panel according to claim 1, wherein refractive indexes of the at least two organic film layers increase with increase of a distance from the display substrate.

7. The display panel according to claim 2, wherein the at least two organic film layers comprise:
a first organic layer, provided on the light-emitting side of the display substrate, wherein the leveling enhancement layer is provided on a side of the first organic layer away from the display substrate; and
a second organic layer, provided on a side of the leveling enhancement layer away from the display substrate;
wherein a concave structure is provided on a side of the first organic layer close to the leveling enhancement layer, and a part of the second organic layer located in the concave structure forms a convex structure.

8. The display panel according to claim 7, wherein an orthographic projection of one protruding structure on the display substrate overlaps at least partially with one sub-pixel, or orthographic projections of a plurality of the protruding structures on the display substrate overlap at least partially with one sub-pixel.

9. The display panel according to claim 1, wherein the display panel further comprises:
a second light enhancement layer provided between the first light enhancement layer and the encapsulation layer group, wherein a refractive index of the second light enhancement layer is greater than a refractive index of a film layer adjacent to the second light enhancement layer in the encapsulation layer group.

10. The display panel according to claim 1, wherein the display panel further comprises:
a buffer layer provided on a side of the first light enhancement layer close to the encapsulation layer group, wherein a material of the buffer layer is a liquid-repellent material; and
a planarization layer provided on a side of the first light enhancement layer away from the display substrate, wherein a refractive index of the first light enhancement layer is greater than a refractive index of the planarization layer.

11. The display panel according to claim 1, wherein at least two stacked organic film layers form an organic film layer group, and the encapsulation layer group further comprises:
a first inorganic layer, provided between the display substrate and the organic film layer group; and
a second inorganic layer, provided on a side of the organic film layer group away from the display substrate.

12. A method for manufacturing a display panel, comprising:
providing a display substrate, wherein the display substrate comprises a plurality of sub-pixels;
forming an encapsulation layer group on a light-emitting side of the display substrate, wherein the encapsulation layer group comprises at least two stacked organic film layers; and
forming a first light enhancement layer on a side of the encapsulation layer group away from the display substrate, wherein the first light enhancement layer comprises a plurality of protruding portions, and orthographic projections of the protruding portions on the display substrate at least partially overlap with the sub-pixels.

13. The method for manufacturing the display panel according to claim 12, wherein forming the encapsulation layer group on the light-emitting side of the display substrate comprises:
forming a first organic layer on the light-emitting side of the display substrate;
forming a leveling enhancement layer on a side of the first organic layer away from the display substrate by plasma-treating the first organic layer; and
forming a second organic layer on a side of the leveling enhancement layer away from the display substrate.

14. The method for manufacturing the display panel according to claim 13, wherein the plasma treatment comprises a fluorination treatment or an oxidation treatment.

15. A display device, comprising:
a display panel according to claim 1.
